(19) United States
(12) Patent Application Publication
(10) Pub. No.: US 2013/0021743 A1
(43) Pub. Date: Jan. 24, 2013

(54) EXPANSION CARD MOUNTING ASSEMBLY

(71) Applicants: Jing-Ling HU, Wuhan City (CN); Zhi-Ping WU, Wuhan City (CN); Xu-Dong NAN, Wuhan City (CN)

(72) Inventors: Jing-Ling HU, Wuhan City (CN); Zhi-Ping WU, Wuhan City (CN); Xu-Dong NAN, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/478,278

(22) Filed: May 23, 2012

(30) Foreign Application Priority Data
Jul. 19, 2011 (CN) 201110202087.7

(51) Int. Cl. H05K 7/14

(52) U.S. Cl. 361/679.32; 248/225.11; 248/220.21

(57) ABSTRACT

An expansion card mounting assembly includes an expansion card and a chassis. The expansion card includes a slot cover having a fixing portion. The chassis includes a bottom plate and a rear plate. The rear plate includes a supporting piece. A flange is connected to a top edge of the rear plate. A first mounting member is mounted on the bottom plate. A second mounting member includes a first piece and a second piece. A bridge piece and a bent piece is connected to the second piece to surround an engaging space. The first piece of the second member presses the fixing portion of the expansion card on the supporting piece. The flange of the rear plate engages in the engaging space. The first mounting member secures an edge of the expansion card.

### TECHNICAL FIELD

The present disclosure relates to mounting assemblies, and particularly to a mounting assembly which can readily and firmly secures an expansion card in a computer chassis.

### DESCRIPTION OF RELATED ART

Many computer systems and other electronic devices employ circuit cards, such as expansion cards, adapters, and PC boards. These cards or boards are typically mounted perpendicularly to a computer motherboard. In particular, the cards are usually inserted into edge card connectors mounted on the computer motherboard. However, merely inserting a card into an edge card connector is insufficient to securely maintain the card within the computer chassis. Cards connected to the motherboard in this fashion can easily disconnect from the edge connector, which may prevent or significantly inhibit acceptable operations of the computer. Accordingly, additional structure is used to secure the card within a computer chassis. A method of securing the card within the computer chassis is to provide a card bracket fastened to the computer chassis with a removable screw. Specifically, each mounting bracket is normally disposed across a card slot formed in the computer chassis and may include an aperture through which the fastener may pass. However, one significant disadvantage of a screw-secured bracket is that the fastener is often inadvertently dropped into the computer chassis during installation and removal of the bracket.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting assembly for an expansion card in an embodiment.

FIG. 2 is an isometric view of a second mounting member of the mounting assembly of FIG. 1.

FIG. 3 is an assembled view of the mounting assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

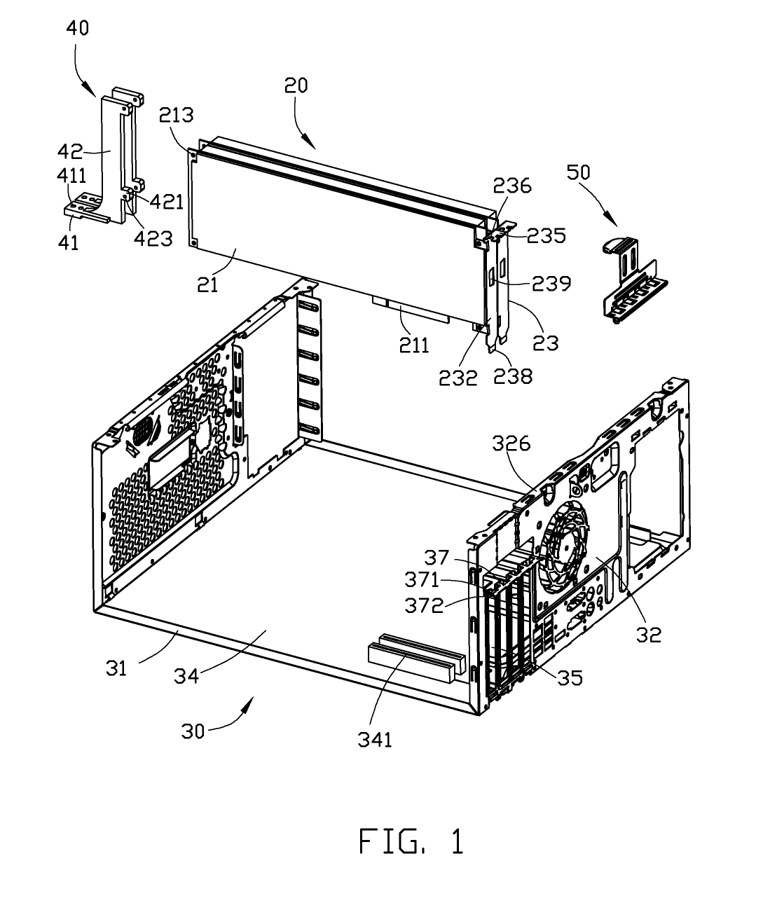

Referring to FIG. 1, an embodiment of an expansion card mounting assembly is used to mount an expansion card 20. The mounting assembly includes a chassis 30, a first mounting member 40, and a second mounting member 50.

The chassis 30 includes a bottom plate 31 and a rear plate 32. The rear plate 32 is perpendicularly connected to an edge of the bottom plate 31. A printed circuit board (PCB) 34 is mounted on the bottom plate 31. A plurality of expansion slots 341 are located on the PCB 34. The rear plate 32 defines a plurality of receiving slots 35 in alignment with the plurality of expansion slots 341. A supporting piece 37 is located above the plurality of receiving slots 35. The supporting piece 37 includes a plurality of pins 371 corresponding to the plurality of receiving slots 35. Opposite's ends of the supporting piece 37 form a pair of protrusions 372. A flange 326 is connected to a top edge of the rear plate 32.

The expansion card 20 includes a main body 21. A connecting edge 211 is mounted on a bottom portion of the main body 21. An “L”-shaped slot cover 23 is mounted on an edge of the expansion card 20. The slot cover 23 includes a shielding piece 232 adapted to cover the receiving slot 35, and a fixing portion 235 bent form a top end of the shielding piece 232. The shielding piece 232 defines a through opening 239, which can receive a connector to connect to the expansion card 20. A bottom portion of the shielding piece 232 is an insert portion 238. The fixing portion 235 defines a cutout 236. Another edge of the expansion card 20, which is opposite to the edge mounted with the slot cover 23, defines two through holes 213.

The first mounting member 40 is formed in an “L” shape. The first mounting member 40 includes a base 41 and a stand 42 perpendicularly connected to the base 41. The base 41 defines two securing holes 411. The stand 42 forms two blocks 421. Each block 421 defines a mounting hole 423.

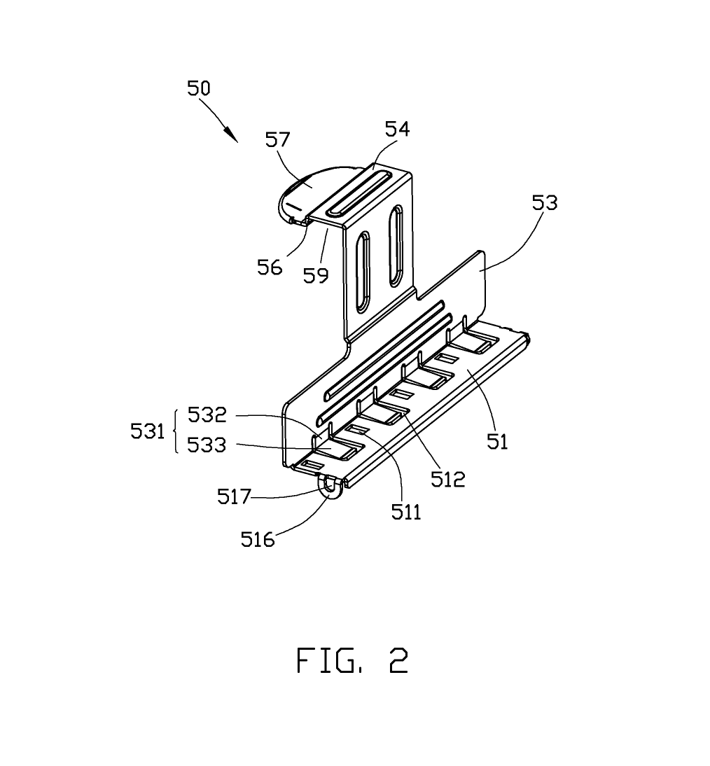

Referring to FIG. 2, the second mounting member 50 includes a first piece 51 and a second piece 53 perpendicularly connected to the first piece 51. The first piece 51 defines a plurality of apertures 511 corresponding to the plurality of pins 371 of the supporting piece 37. Opposite ends of the first piece 51 form a pair of ear pieces 516. Each of the pair of ear pieces 516 defines a receiving hole 517. The first piece 51 defines a plurality of receiving openings 512 corresponding to the plurality of receiving slots 35 of the rear plate 32. The plurality of receiving openings 512 are adjacent to the second piece 53. A plurality of pressing pieces 531 are connected to the second piece 53. Each of the plurality of pressing pieces 531 includes a connecting portion 532 and a pressing portion 533 connected to the connecting portion 532. The connecting portion 532 is connected to the second piece 53. The pressing portion 533 is received in the receiving opening 512 and can be elastically bent. A top portion of the second piece 53 is perpendicularly bent to form a bridge piece 54. A free edge of the bridge piece 54 is bent to forms a bent piece 56. An engaging space 59 is surrounded by the second piece 53, the bridge piece 54, and the bent piece 56. A handle 57 is connected to the bent piece 56. The handle 57 can be pulled to elastically bend the second piece 53.

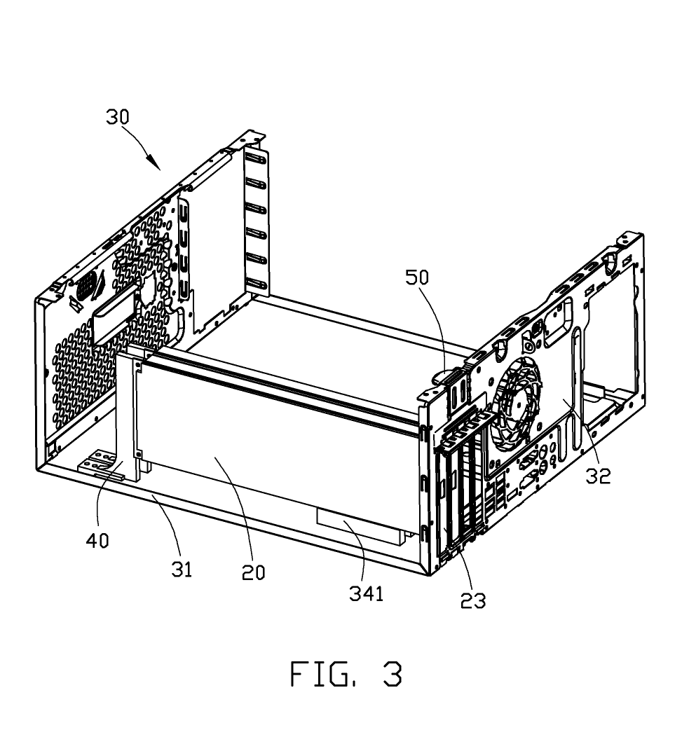

Referring to FIGS. 1 to 3, in assembly, the slot cover 23 of the expansion card 20 covers on one receiving slot 35 of the rear plate 32. The fixing portion 235 is located on the supporting piece 37. One of the plurality of pins 371 of the supporting piece 37 is inserted on the cutout 236 of the fixing portion 235. The connecting edge 211 of the expansion card 20 is inserted in the expansion slot 341 of the PCB 34.

The first piece 51 of the second mounting member 50 is located on the supporting piece 37. The pressing portion 533 of one of the plurality of pressing pieces 531 presses on the fixing portion 235 of the expansion card 20. The pin 371 is inserted in the apertures 511. The protrusions 372 of the rear plate 32 are secured in the receiving holes 517 of the first piece 51. The flange 326 of the rear plate 32 is received in the engaging space 59 of the second mounting member 50. Therefore, the second mounting member 50 is mounted on the rear plate 32 to fix the fixing portion of the expansion card 20 on the supporting piece 37.

The base 41 of the first mounting member 40 is placed on the bottom plate 31. The base 41 is mounted on bottom plate 31 with known means, such as pivots, screws, and so on. Therefore, the first mounting member 40 is mounted on the bottom plate 31. The mounting holes 423 of the first mounting member 40 are aligned to the through holes 213 of the expansion card 20. A plurality of fasteners (not shown) are secured in the mounting holes 423 and the through holes 213 to secure the expansion card 20 to the first mounting member 40. The expansion card 20 is firmly mounted in the chassis 30.

In the above mounting assembly, opposite edges of the expansion card 20 are secured to the chassis 30 by the first mounting member 40 and the second mounting member 50. The expansion card 20 is secured in the chassis 30 firmly.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. An expansion card mounting assembly, comprising:
an expansion card comprising a slot cover and a fixing portion;
a chassis comprising a bottom plate and a rear plate connected to the bottom plate, the rear plate comprising a supporting piece, a flange connected to a top edge of the rear plate;
a first mounting member mounted on the bottom plate; and
a second mounting member comprising a first piece and a second piece connected to the first piece, a bridge piece connected to a top portion of the second piece, a bent piece connected to a free edge of the bridge piece, an engaging space being surrounded by the second piece, the bridge piece, and the bent piece;
wherein the first piece of the second member is adapted to press the fixing portion onto the supporting piece, the flange of the rear plate is adapted to engage in the engaging space, and the first mounting member is adapted to secure an edge of the expansion card.

2. The expansion card mounting assembly of claim 1, wherein the rear plate is generally perpendicularly connected to the bottom plate.

3. The expansion card mounting assembly of claim 1, wherein the slot cover defines a through opening, and the through opening is configured to receive a connector to connect to the expansion card.

4. The expansion card mounting assembly of claim 1, wherein the first mounting member comprises a base and a stand connected to the base, the base is secured to the bottom plate, and the stand is secured to the edge of the expansion card.

5. The expansion card mounting assembly of claim 4, wherein the stand forms a block, the block defines a mounting hole, the expansion card defines a through hole, and the mounting hole is aligned to the through hole.

6. The expansion card mounting assembly of claim 1, wherein the fixing portion defines a cutout, the supporting piece comprises a pin, and the pin is received in the cutout.

7. The expansion card mounting assembly of claim 1, wherein an ear piece is connected to the first piece, the ear piece defines a receiving hole, the supporting piece comprises a protrusion, and the protrusion is configure to be inserted in the receiving hole.

8. The expansion card mounting assembly of claim 1, wherein the first piece defines a receiving opening, a pressing piece is connected to the second piece and located in the receiving opening, and the pressing piece is adapted to be elastically deformed to press the fixing portion.

9. The expansion card mounting assembly of claim 1, wherein a handle is connected to the bent piece.

10. An expansion card mounting assembly, comprising:
a bottom plate, a first mounting member mounted on the bottom plate; and
a rear plate connected to the bottom plate, a second mounting member mounted on the rear plate;
wherein the first mounting member and the second mounting member are adapted to secure opposite edges of an expansion card.

11. The expansion card mounting assembly of claim 10, wherein the rear plate is generally perpendicularly connected to the bottom plate.

12. The expansion card mounting assembly of claim 10, wherein the first mounting member comprises a base and a stand connected to the base, the base is secured to the bottom plate, and the stand is secured to an edge of the expansion card.

13. The expansion card mounting assembly of claim 12, wherein the stand forms a block, the block defines a mounting hole, the expansion card defines a through hole, and the mounting hole is aligned to the through hole.

14. The expansion card mounting assembly of claim 10, wherein the rear plate defines a receiving slot, a supporting piece is located on the receiving slot, the expansion card comprises a slot cover, the slot cover comprises a fixing portion, the slot cover covers the receiving slot and the fixing portion is placed on the supporting piece.

15. The expansion card mounting assembly of claim 14, wherein the fixing portion defines a cutout, the supporting piece comprises a pin, and the pin is received in the cutout.

16. The expansion card mounting assembly of claim 14, wherein the second mounting member comprises a first piece, an ear piece is connected to the first piece, the ear piece defines a receiving hole, the supporting piece comprises a protrusion, the first piece is adapted to press the fixing portion onto the supporting piece, and the protrusion is configured to be inserted in the receiving hole.

17. The expansion card mounting assembly of claim 16, wherein the second mounting member comprises a second piece perpendicularly connected to the first piece, the first piece defines a receiving opening, a pressing piece is connected to the second piece and located in the receiving opening, and the pressing piece is adapted to be elastically deformed to press the fixing portion.

18. The expansion card mounting assembly of claim 17, wherein a top portion of the second piece is bent to form a bridge piece, a free edge of the bridge piece is bent to forms a bent piece, an engaging space is surrounded by the second piece, the bridge piece, and the bent piece, a flange is connected to a top edge of the rear plate, and the flange is received in the engaging space.

19. The expansion card mounting assembly of claim 18, wherein a handle is connected to the bent piece.
